(19) United States
(12) Patent Application Publication
(10) Pub. No.: US 2025/0346718 A1
(43) Pub. Date: Nov. 13, 2025

(54) POLYIMIDE PRECURSOR COMPOSITION AND POLYIMIDE FILM COMPRISING SAME

(71) Applicant: PI ADVANCED MATERIALS CO., LTD., Chungcheongbuk-do (KR)

(72) Inventors: Sung-Yul BACK, Seoul (KR); Dong-Young WON, Jincheon-gun (KR); Kil-Nam LEE, Bucheon-si (KR); Min-Sang CHO, Incheon (KR); Su-Kyung CHAE, Incheon (KR); Young-Jin JUNG, Seoul (KR)

(73) Assignee: PI ADVANCED MATERIALS CO., LTD., Chungcheongbuk-do (KR)

(21) Appl. No.: 18/712,248

(22) PCT Filed: Nov. 21, 2022
(86) PCT No.: PCT/KR2022/018423

§ 371 Date: Nov. 22, 2024

(30) Foreign Application Priority Data
Nov. 22, 2021 (KR) 10-2021-0161643
Aug. 30, 2022 (KR) 10-2022-0109102

(51) Int. Cl. C08G 73/10; C08J 5/18; H05K 1/02

(52) U.S. Cl. CPC C08G 73/1042; C08G 73/1067; C08J 5/18; C08J 2379/08; H05K 1/024; H05K 2201/0154

(57) ABSTRACT

The present invention provides a polyimide film comprising a block copolymer, the block copolymer comprising: a first block obtained by imidizing polyamic acid derived from a polymer consisting of a dianhydrous acid component including biphenyltetracarboxylic dianhydride and a diamine component including paraphenylenediamine; a second block obtained by imidizing polyamic acid derived from a polymer consisting of a dianhydrous acid component including biphenyltetracarboxylic dianhydride and a diamine component including m-tolidine; and a third block obtained by imidizing polyamic acid derived from a polymer consisting of a dianhydrous acid component including pyromellitic dianhydride (PMDA) and a diamine component including m-tolidine.

### TECHNICAL FIELD

The present disclosure relates to a polyimide precursor composition and a polyimide film having excellent highly heat-resistant properties, low-dielectric properties, and dimensional stability properties, the polyimide film being prepared using the polyimide precursor composition.

### BACKGROUND ART

Polyimide (PI) is a polymeric material having the highest level of heat resistance, chemical compatibility, electrical insulation, chemical resistance, and weather resistance of all organic materials on the basis of an imide ring having excellent chemical stability along with a rigid aromatic main chain.

In particular, polyimide is attracting attention as a highly functional polymeric material in electrical, electronic, and optical fields due to having excellent insulation properties, that is, excellent electrical properties such as a low dielectric constant.

Recently, with weight reduction and size reduction in electronic products, flexible thin circuit boards with high integration density are being actively developed.

Such thin circuit boards tend to have a structure in which a circuit including a metal foil is formed on a polyimide film having excellent heat resistance, low-temperature resistance, and insulation properties while being easily bendable, which are widely used.

Flexible metal-clad laminates are mainly used as the thin circuit board, and examples thereof include flexible copper-clad laminates (FCCLs) using a thin copper plate as a metal foil. Furthermore, polyimide is also used in protective films, insulating films, and the like for thin circuit boards.

On the other hand, with various built-in functions in electronic devices, there has recently been a growing need to apply fast calculation and communication speeds to such devices. Additionally, thin circuit boards capable of high-speed communication based on high frequencies are being developed to meet these requirements.

There is a need for an insulator with a high impedance capable of maintaining electrical insulation properties even at high frequencies to realize high-speed communication at high frequencies. Impedance is inversely proportional to the dielectric constant (Dk) and frequency formed in the insulator, so the dielectric constant must be as low as possible to maintain insulation properties even at high frequencies.

However, in the case of existing polyimide, the level of dielectric properties is not excellent enough to maintain sufficient insulation properties in high-frequency communication.

Additionally, it is known that when an insulator has low-dielectric properties, the stray capacitance and noise, undesirably occurring in thin circuit boards, are likely to be reduced, thereby eliminating most of the causes of communication delays.

Therefore, polyimide having low-dielectric properties is recognized as the most important factor in the performance of thin circuit boards.

In particular, in the case of high-frequency communication, dielectric dissipation inevitably occurs through polyimide. A dielectric dissipation factor (Df) refers to the degree of electrical energy wasted in a thin circuit board and is closely related to signal transmission delays that determine communication speed. Thus, keeping the dielectric dissipation factor of polyimide as low as possible is also recognized as a key factor in the performance of thin circuit boards.

Additionally, the more moisture contained in a polyimide film, the greater the dielectric constant and the higher the dielectric dissipation factor. While being suitable as materials for thin circuit boards due to having excellent inherent properties, polyimide films may be relatively vulnerable to moisture due to the polar imide group, leading to deterioration in insulation properties.

Therefore, there is a need to develop a polyimide film having dielectric properties, especially a low dielectric dissipation factor, while maintaining the unique mechanical properties, thermal properties, and dimensional stability properties of polyimide to a predetermined level.

### DOCUMENT OF RELATED ART

### Patent Document

(Patent Document 1) Korean Patent Application Publication No. 10-2015-0069318

### DISCLOSURE

### Technical Problem

Accordingly, to solve the problems described above, the present disclosure aims to provide a polyimide film having excellent highly heat-resistant properties, low-dielectric properties, and dimensional stability properties and a polyamide precursor composition to prepare the same.

Hence, the present disclosure practically aims to provide specific embodiments thereof.

### Technical Solution

In a first embodiment of the present disclosure for achieving the objectives as described above, a polyimide film including a block copolymer including a first block obtainable by imidizing a polyamic acid derived from a polymer of an acid dianhydride component including biphenyl-tetracarboxylic dianhydride (BPDA) and a diamine component including para-phenylenediamine (PPD),
a second block obtainable by imidizing a polyamic acid derived from a polymer of an acid dianhydride component including biphenyl-tetracarboxylic dianhydride and a diamine component including m-tolidine, and
a third block obtainable by imidizing a polyamic acid derived from a polymer of an acid dianhydride component including pyromellitic dianhydride (PMDA) and a diamine component including m-tolidine
is provided.

In a second embodiment of the present disclosure, a multilayer film including the polyimide film and a thermoplastic resin layer
is provided.

In a third embodiment of the present disclosure, a flexible metal-clad laminate including the polyimide film and an electrically conductive metal foil
is provided.

In a fourth embodiment of the present disclosure, an electronic component including the flexible metal-clad laminate
is provided.

In a fifth embodiment of the present disclosure, a polyimide precursor composition including a block copolymer including a first block obtainable by reacting an acid dianhydride component including biphenyl-tetracarboxylic dianhydride (BPDA) and a diamine component including para-phenylenediamine (PPD),
a second block obtainable by reacting an acid dianhydride component including biphenyl-tetracarboxylic dianhydride and a diamine component including m-tolidine through an imidization reaction, and
a third block obtainable by reacting an acid dianhydride component including pyromellitic dianhydride (PMDA) and a diamine component including m-tolidine
is provided.

### Advantageous Effects

As described above, the present disclosure provides a polyimide film having excellent highly heat-resistant properties, low-dielectric properties, and dimensional stability properties through a polyimide film composed of specific components in specific composition ratios and a polyamide precursor composition for preparing the same, which can thus be usefully applied to various fields in need of such properties, especially electronic components such as flexible metal-clad laminates.

### BEST MODE

Hereinafter, embodiments of the present disclosure will be described in more detail.

All terms including technical and scientific terms used herein have the same meaning as commonly understood by those skilled in the art to which the present disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Therefore, the embodiments described herein are merely examples and do not exhaustively present the technical spirit of the present disclosure. Accordingly, it should be appreciated that there may be various equivalents and modifications that can replace the embodiments and the configurations at the time at which the present application is filed.

As used herein, the singular forms are intended to include the plural forms as well, unless the context clearly indicates otherwise. It will be further understood that the terms “comprise”, “include”, “have”, and the like when used herein, specify the presence of stated features, integers, steps, components, or combinations thereof but do not preclude the presence or addition of one or more other features, integers, steps, components, or combinations thereof.

When an amount, concentration, other value, or parameter is given herein as a range, preferred range, or enumeration of preferred upper values and preferred lower values, it is to be understood to specifically disclose all ranges formed by a pair of any upper range limit or a preferred value and any lower range limit or a preferred value, regardless of whether the ranges are additionally disclosed.

When a range of numerical values is mentioned herein, this range is intended to include not only the endpoints but also all integers and fractions within the range, unless otherwise stated. The scope of the present disclosure is not intended to be limited to the specific values mentioned when defining the scope.

As used herein, although the term “acid dianhydride” is intended to include precursors or derivatives thereof, these compounds may not technically be acid dianhydride. Nevertheless, these compounds will react with diamine to form polyamic acids, which will be converted to polyimides once more.

As used herein, although the term “diamine” is intended to include precursors or derivatives thereof, these compounds may not technically be diamines. Nevertheless, these compounds will react with dianhydride to form polyamic acids, which will be converted to polyimides once more.

A polyimide film, according to the present disclosure, may include a block copolymer including: a first block obtainable by imidizing a polyamic acid derived from a polymer of an acid dianhydride component including biphenyl-tetracarboxylic dianhydride (BPDA) and a diamine component including para-phenylenediamine (PPD); a second block obtainable by imidizing a polyamic acid derived from a polymer of an acid dianhydride component including biphenyl-tetracarboxylic dianhydride and a diamine component including m-tolidine; and a third block obtainable by imidizing a polyamic acid derived from a polymer of an acid dianhydride component including pyromellitic dianhydride (PMDA) and a diamine component including m-tolidine.

For example, the first block may be obtainable by reacting the polyamic acid derived from the polymer of biphenyl-tetracarboxylic dianhydride and para-phenylenediamine through an imidization reaction, the second block may be obtained by reacting the polyamic acid derived from the polymer of biphenyl-tetracarboxylic dianhydride and m-tolidine through an imidization reaction, and the third block may be obtainable by reacting the polyamic acid derived from the polymer of pyromellitic dianhydride and m-tolidine through an imidization reaction.

The m-tolidine has a hydrophobic methyl group and thus contributes to the low hygroscopicity of the polyimide film and the resulting low-dielectric properties of the polyimide film.

In one embodiment, the polyimide film may be obtainable by imidizing the polyamic acid derived from the polymer of the acid dianhydride component including biphenyl-tetracarboxylic dianhydride and pyromellitic dianhydride and the diamine component including para-phenylenediamine and m-tolidine.

This is because the polyimide film may include the first, second, and third blocks or may be made of the block copolymer including the first, second, and third blocks.

In one embodiment, m-tolidine may have a content of 25 mol % or more and 40 mol % or less, and para-phenylenediamine may have a content of 60 mol % or more and 75 mol % or less, based on 100 mol % of the total content of the diamine component in the polyimide film.

Preferably, m-tolidine has a content of 30 mol % or more and 40 mol % or less, and para-phenylenediamine has a content of 60 mol % or more and 70 mol % or less, based on 100 mol % of the total content of the diamine component in the polyimide film.

Additionally, biphenyl-tetracarboxylic dianhydride may have a content of 50 mol % or more and 65 mol % or less, and pyromellitic dianhydride may have a content of 35 mol % or more and 50 mol % or less, based on 100 mol % of the total content of the acid dianhydride component in the polyimide film.

Preferably, biphenyl-tetracarboxylic dianhydride has a content of 50 mol % or more and 60 mol % or less, and pyromellitic dianhydride has a content of 40 mol % or more and 50 mol % or less, based on 100 mol % of the total content of the acid dianhydride component in the polyimide film.

The polyimide chain of the present disclosure, derived from biphenyl-tetracarboxylic dianhydride, has a structure called a charge transfer complex (CTC), that is, a regular linear structure in which an electron donor and an electron acceptor are positioned close to each other, and the intermolecular interaction is strengthened.

Such a structure is effective in preventing hydrogen bonding with moisture and thus has an impact on reducing the moisture absorption rate, thereby maximizing the effect of reducing the hygroscopicity of the polyimide film.

In one specific example, the acid dianhydride component may further include pyromellitic dianhydride. Pyromellitic dianhydride, the acid dianhydride component having a relatively rigid structure, is preferable in terms of providing appropriate elasticity to the polyimide film.

In order for the polyimide film to satisfy both appropriate elasticity and moisture absorption rate, the content ratio of acid dianhydride is particularly important. For example, as the content ratio of biphenyl-tetracarboxylic dianhydride decreases, a low moisture absorption rate based on the CTC structure is hard to expect.

Additionally, while biphenyl-tetracarboxylic dianhydride contains two benzene rings corresponding to the aromatic moiety, pyromellitic dianhydride contains one benzene ring corresponding to the aromatic moiety.

The increase in the pyromellitic dianhydride content in the acid dianhydride component may be understood as an increase in the imide group within the molecule based on the same molecular weight, indicating that the ratio of the imide group derived from the pyromellitic dianhydride in the polyimide polymer chain increases relatively compared to that of the imide group derived from biphenyl-tetracarboxylic dianhydride.

In other words, an increase in the pyromellitic dianhydride content may be seen as a relative increase in the imide group in the entire polyimide film, making it difficult to expect a low moisture absorption rate.

On the contrary, when the content ratio of pyromellitic dianhydride decreases, this means that the component having a relatively rigid structure is reduced, so the elasticity of the polyimide film may deteriorate below the desired level.

For this reason, when the biphenyl-tetracarboxylic dianhydride content exceeds the above range or the pyromellitic dianhydride content is lower than the above range, the mechanical properties of the polyimide film deteriorate, and an appropriate level of heat resistance required to manufacture a flexible metal-clad laminate may not be obtainable.

On the contrary, when the biphenyl-tetracarboxylic dianhydride content is lower than the above range or the pyromellitic dianhydride content exceeds the above range, appropriate levels of dielectric constant and dielectric dissipation factor may be challenging to achieve, which is undesirable.

In one embodiment, the biphenyl-tetracarboxylic dianhydride in the first block may have a content of 40 mol % or more and 55 mol % or less based on 100 mol % of the total content of the acid dianhydride component in the polyimide film. Additionally, the biphenyl-tetracarboxylic dianhydride in the second block may have a content of 10 mol % or more based on 100 mol % of the total content of the acid dianhydride component in the polyimide film.

When the biphenyl-tetracarboxylic dianhydride content in the first block is lower than the above range, a sufficiently low dielectric dissipation factor (Df) may be challenging to obtain, and when the biphenyl-tetracarboxylic dianhydride content in the first block exceeds the above range, the necessary heat resistance may be challenging to obtain.

When the biphenyl-tetracarboxylic dianhydride content in the second block is lower than the above range, a sufficiently low dielectric dissipation factor (Df) may be challenging to obtain.

On the other hand, the biphenyl-tetracarboxylic dianhydride in the second block may have a content of 25 mol % or less based on 100 mol % of the total content of the acid dianhydride component in the polyimide film.

When the biphenyl-tetracarboxylic dianhydride content in the second block exceeds the above range, the necessary heat resistance may be challenging to obtain.

Additionally, the biphenyl-tetracarboxylic dianhydride in the first block may be imidized completely with para-phenylenediamine, and the biphenyl-tetracarboxylic dianhydride in the second block may be imidized completely with m-tolidine.

On the other hand, the m-tolidine in the third block may have a content of 10 mol % or more and 35 mol % or less based on 100 mol % of the total content of the diamine component in the polyimide film.

When the m-tolidine content in the third block is lower than the above range, a sufficiently low dielectric dissipation factor (Df) may be challenging to obtain, and when the m-tolidine content in the third block exceeds the above range, the necessary heat resistance may be challenging to obtain.

Additionally, the m-tolidine in the third block may be imidized completely with pyromellitic dianhydride.

In one embodiment, the polyimide film may have a dielectric dissipation factor (Df) of 0.003 or less, a coefficient of thermal expansion (CTE) of 13 ppm/° C. or higher and 23 ppm/° C. or lower, and a glass transition temperature (Tg) of 320° C. or higher.

In this regard, a polyimide film satisfying all of the dielectric dissipation factor (Df), coefficient of thermal expansion, and glass transition temperature may be used as an insulating film for flexible metal-clad laminates. Furthermore, even when using such manufactured flexible metal-clad laminates as an electrical signal transmission circuit to transmit signals at a high frequency of 10 GHz or higher, the insulation stability thereof may be obtainable, and the signal transmission delays may be minimized.

While the polyimide film satisfying all of the conditions described above is a novel polyimide film that has not been known so far, the dielectric dissipation factor (Df) will be described in detail below.

### <Dielectric Dissipation Factor>

“Dielectric dissipation factor” means the force dissipated by a dielectric (or insulator) when the friction of molecules obstructs the molecular motion caused by an alternating electric field.

The value of the dielectric dissipation factor is commonly used as an index to describe the ease of charge loss (dielectric dissipation). The higher the dielectric dissipation factor, the easier charge loss occurs. On the contrary, the lower the dielectric dissipation factor, the more difficult charge loss occurs. In other words, the dielectric dissipation factor is a measure of power loss, so communication speed may remain faster with the lower dielectric dissipation factor while mitigating signal transmission delays caused by power loss.

This is strongly required for the polyimide film, which is an insulating film, so the polyimide film, according to the present disclosure, may have a dielectric dissipation factor of 0.003 or less under an extremely high frequency of 10 GHz.

The preparation of the polyamic acid in the present disclosure may, for example, involve:
(1) a polymerization method by adding the entire amount of the diamine component in a solvent and then adding the acid dianhydride component so that the amount thereof is substantially equimolar to that of the diamine component;
(2) a polymerization method by adding the entire amount of the acid dianhydride component in a solvent and then adding the diamine component so that the amount thereof is substantially equimolar to that of the acid dianhydride component;
(3) a polymerization method by adding some of the diamine component to a solvent, mixing some of the acid dianhydride component in a ratio of about 95 to 105 mol % to the reaction component, adding the remaining diamine component, and then subsequently adding the remaining acid dianhydride component so that the diamine component and the acid dianhydride component are substantially equimolar;
(4) a polymerization method by adding some of the acid dianhydride component to a solvent, mixing some of the diamine compound in a ratio of about 95 to 105 mol % to the reaction component, adding the remaining acid dianhydride component, and then subsequently adding the remaining diamine component so that the diamine component and the acid dianhydride component are substantially equimolar;
(5) a polymerization method by reacting some of the diamine component and some of the acid dianhydride component in a first solvent so that either one is in excess to form a first composition, reacting some of the diamine component and some of the acid dianhydride component in a second solvent so that either one is in excess to form a second composition, and mixing the first and second compositions to complete polymerization, wherein when the diamine component is in excess when forming the first composition, the acid dianhydride component in the second composition is contained in an excessive amount, and when the acid dianhydride component is in excess in the first composition, the diamine component in the second composition is contained in an excessive amount to mix the first and second compositions so that the entire diamine component and acid dianhydride component used in the reaction are substantially equimolar; and the like.

In the present disclosure, such a polymerization method of the polyamic acid described above may be defined as a random polymerization method. Additionally, the polyimide film of the present disclosure, formed from the polyamic acid prepared through such a process described above, is preferably applicable for maximizing the effect of the present disclosure in reducing the dielectric dissipation factor and moisture absorption rate.

However, the polymerization method makes the length of the repeating unit in the polymer chain described above relatively short, so there may be limitations in demonstrating each of the excellent properties of the polyimide chain derived from the acid dianhydride component. Therefore, block polymerization may be performed as the polymerization method of the polyamic acid, which is further preferably usable in the present disclosure.

On the other hand, the solvent for synthesizing the polyamic acid is not particularly limited, and any solvent capable of dissolving the polyamic acid may be usable. However, an amide-based solvent is preferably used.

Specifically, the solvent may be a polar organic solvent, which may be, in particular, a polar aprotic solvent. Examples thereof may include one or more selected from the group consisting of N,N-dimethylformamide (DMF), N,N-dimethylacetamide, N-methyl-pyrrolidone (NMP), gamma-butyrolactone (GBL), and diglyme, but the solvent is not limited thereto. If necessary, the solvent may be used alone, or two or more types may be used in combination.

In one example, N,N-dimethylformamide and N,N-dimethylacetamide are further preferably used as the solvent.

Additionally, in the polyamic acid preparation process, fillers may be added to improve various properties of the film, such as sliding properties, thermal conductivity, corona resistance, loop hardness, and the like. The filler added is not particularly limited, but preferred examples thereof include silica, titanium oxide, alumina, silicon nitride, boron nitride, calcium hydrogen phosphate, calcium phosphate, mica, and the like.

The particle diameter of the filler is not particularly limited but may be determined depending on the properties of a film to be modified and the type of fillers to be added. Typically, the average particle diameter is in a range of 0.05 to 100 μm, which is preferably in the range of 0.1 to 75 μm, more preferably in the range of 0.1 to 50 μm, and even more preferably in the range of 0.1 to 25 μm.

When the particle diameter is smaller than the above range, the modification effect may be challenging to exhibit, and when the particle diameter exceeds the above range, the surface properties may be seriously damaged, or the mechanical properties may significantly deteriorate.

Additionally, the amount of the filler added is not particularly limited but may be determined by the properties of a film to be modified, the particle diameter of the filler, or the like. Typically, the amount of the filler added is in a range of 0.01 to 100 parts by weight with respect to 100 parts by weight of the polyimide, which is preferably in the range of 0.01 to 90 parts by weight and more preferably in the range of 0.02 to 80 parts by weight.

When the amount of the filler added is smaller than the above range, the modification effect by the filler may be challenging to exhibit, and when the amount of the filler added exceeds the above range, the mechanical properties of the film may be seriously damaged. The method of adding the filler is not particularly limited, and any known methods may be used.

In the formation method of the present disclosure, the polyimide film may be formed by a thermal imidization method and a chemical imidization method.

Additionally, the polyimide film may be formed by a complex imidization method in combination of the thermal imidization and chemical imidization methods.

The thermal imidization method is a method of inducing an imidization reaction using a heat source such as an infrared dryer or hot air, without involving a chemical catalyst.

The thermal imidization method may enable the amic acid group present in a gel film to be imidized by subjecting the gel film to heat treatment at a variable temperature in a range of 100° C. to 600° C. Specifically, the heat treatment may be performed at a temperature in a range of 200° C. to 500° C., which is more specifically in the range of 300° C. to 500° C., to imidize the amic acid group present in the gel film.

However, even in the gel film formation process, some of the amic acid (about 0.1 to 10 mol %) may be imidized. To this end, the polyamic acid composition may be dried at a variable temperature in a range of 50° C. to 200° C., which may also fall within the scope of the thermal imidization method.

In the case of the chemical imidization method, a dehydrating agent and an imidizing agent may be used according to methods known in the art to form the polyimide film.

As one example of the complex imidization method, a dehydrating agent and an imidizing agent may be introduced into a polyamic acid solution, heated at a temperature in a range of 80° C. to 200° C., which is preferably in the range of 100° C. to 180° C., partially cured and dried, and then heated at a temperature in a range of 200° C. to 400° C. for 5 to 400 seconds, thereby forming the polyimide film.

The polyimide film of the present disclosure, formed according to the formation method described above, may have a dielectric dissipation factor (Df) of 0.004 or less, a coefficient of thermal expansion (CTE) of 15 ppm/° C. or lower, and a glass transition temperature (Tg) of 320° C. or higher.

The present disclosure provides: a multilayer film including the polyimide film described above and a thermoplastic resin layer; and a flexible metal-clad laminate including the polyimide film described above and an electrically conductive metal foil.

Examples of the thermoplastic resin layer used may include a thermoplastic polyimide resin layer and the like.

The metal foil used is not particularly limited. However, when using the flexible metal-clad laminate of the present disclosure for electronic or electrical devices, the metal foil may, for example, include copper or an alloy thereof, stainless steel or an alloy thereof, nickel or an alloy thereof (including Alloy 42), and aluminum or an alloy thereof.

In typical flexible metal-clad laminates, copper foils, such as rolled copper foil and electrolytic copper foil, are widely used and are also preferably used in the present disclosure. Additionally, the surface of such metal foils may be coated with an anti-rust layer, a heat-resistant layer, or an adhesive layer.

The thickness of the metal foil is not particularly limited in the present disclosure and may be any thickness capable of demonstrating sufficient functions depending on the intended use.

The flexible metal-clad laminate, according to the present disclosure, may have a structure in which the metal foil is laminated onto one surface of the polyimide film or a structure in which an adhesive layer containing thermoplastic polyimide is added to one surface of the polyimide film, and the metal foil is laminated while being attached to the adhesive layer.

Additionally, the present disclosure provides an electronic component including the flexible metal-clad laminate as an electrical signal transmission circuit. The electrical signal transmission circuit may be an electronic component configured to transmit signals at a high frequency of at least 2 GHZ, specifically at a high frequency of at least 5 GHZ, and more specifically at a high frequency of at least 10 GHz.

Examples of the electronic component may include a communication circuit for a mobile phone, a communication circuit for a computer, or a communication circuit for aerospace but are not limited thereto.

On the other hand, a polyimide precursor composition, according to the present disclosure, may include a block copolymer including: a first block obtainable by reacting an acid dianhydride component including biphenyl-tetracarboxylic dianhydride (BPDA) and a diamine component including para-phenylenediamine (PPD); a second block obtainable by reacting an acid dianhydride component including biphenyl-tetracarboxylic dianhydride and a diamine component including m-tolidine; and a third block obtainable by reacting an acid dianhydride component including pyromellitic dianhydride (PMDA) and a diamine component including m-tolidine.

The acid dianhydride and diamine components of the block copolymer may consist only of biphenyl-tetracarboxylic dianhydride, pyromellitic dianhydride, para-phenylenediamine, and m-tolidine.

In one embodiment, m-tolidine may have a content of 25 mol % or more and 40 mol % or less, and para-phenylenediamine may have a content of 60 mol % or more and 75 mol % or less, based on 100 mol % of the total content of the diamine component of the block copolymer. Additionally, biphenyl-tetracarboxylic dianhydride may have a content of 50 mol % or more and 65 mol % or less, and pyromellitic dianhydride may have a content of 35 mol % or more and 50 mol % or less, based on 100 mol % of the total content of the acid dianhydride component of the block copolymer.

In one embodiment, the biphenyl-tetracarboxylic dianhydride in the first block of the block copolymer may have a content of 40 mol % or more and 55 mol % or less based on 100 mol % of the total content of the acid dianhydride component in the polyimide film. Additionally, the biphenyl-tetracarboxylic dianhydride in the second block may have a content of 10 mol % or more based on 100 mol % of the total content of the acid dianhydride component in the polyimide film.

On the other hand, the biphenyl-tetracarboxylic dianhydride in the second block may have a content of 25 mol % or less based on 100 mol % of the total content of the acid dianhydride component in the polyimide film.

Additionally, the m-tolidine in the third block of the block copolymer may have a content of 10 mol % or more and 35 mol % or less based on 100 mol % of the total content of the diamine component in the polyimide film.

The polyimide precursor composition of the present disclosure may include the block copolymer (polyamic acid) and an organic solvent.

The organic solvent is not particularly limited, and any solvent capable of dissolving the polyamic acid may be usable. However, an amide-based solvent is preferably used.

Specifically, the organic solvent may be a polar organic solvent, which may be, in particular, a polar aprotic solvent. Examples thereof may include one or more selected from the group consisting of N,N-dimethylformamide (DMF), N,N-dimethylacetamide, N-methyl-pyrrolidone (NMP), gamma-butyrolactone (GBL), and diglyme, but the solvent is not limited thereto. If necessary, the solvent may be used alone, or two or more types may be used in combination.

In one example, N,N-dimethylformamide and N,N-dimethylacetamide are further preferably used as the solvent.

On the other hand, the block copolymer (polyamic acid) may be included in an amount in a range of about 5 to 35 wt % (for example, about 5 wt %, about 10 wt %, about 15 wt %, about 20 wt %, about 25 wt %, about 30 wt %, or about 35 wt %) based on the total weight of the polyimide precursor composition. Within the above range, the polyimide precursor composition may have molecular weight and solution viscosity appropriate to form a film, and the storage stability thereof may be excellent. The block copolymer (polyamic acid) may be included in an amount in a range of about 10 to 30 wt % in one example or about 15 to 20 wt % in another example, based on the total weight of the polyimide precursor composition, but is not limited thereto.

Additionally, the polyimide precursor composition may have a viscosity in a range of about 100,000 to 300,000 cP (for example, about 100,000 cP, about 150,000 cP, about 200,000 cP, about 250,000 cP, or about 300,000 cP) at a temperature of 23° C. and a shear rate of 1 s⁻¹.

Within the above range, the block copolymer (polyamic acid) may be allowed to have a predetermined weight average molecular weight while having excellent processability during polyimide film formation. In this case, the “viscosity” may be measured using a HAAKE Mars rheometer.

The polyimide precursor composition may have a viscosity in a range of about 150,000 to 250,000 cP in one example or about 200,000 to 250,000 cP in another example, at a temperature of 23° C. and a shear rate of 1 s⁻¹, but is limited thereto.

The block copolymer (polyamic acid) may have a weight average molecular weight (Mw) of about 100,000 g/mol or greater, for example, in a range of about 100,000 to 500,000 g/mol. Although the above range may be advantageous in forming better polyimide coating films or polyimide films, the weight average molecular weight is not limited thereto. In this case, the “weight average molecular weight” may be measured using gel permeation chromatography (GPC).

The polyimide precursor composition of the present disclosure, provided in a varnish form, may be used to form a polyimide coating film or may be used to form the polyimide film of the present disclosure.

To obtain a polyimide coating film, a substrate is coated with the polyimide precursor composition by a method known in the art, such as a spin coating method, a spray coating method, a screen printing method, a dipping method, a curtain coating method, a dip coating method, a die coating method, and the like, dried at a temperature of 250° C. or lower to remove a solvent, and then imidized.

The polyimide precursor composition of the present disclosure may include other components to the extent that the purpose of the present disclosure is not impaired. Examples of other components may include base generator components, polymerizable components such as monomers, surfactants, plasticizers, viscosity modifiers, anti-foaming agents, colorants, and fillers.

The filler added is not particularly limited, but preferred examples thereof include silica, titanium oxide, alumina, silicon nitride, boron nitride, calcium hydrogen phosphate, calcium phosphate, mica, and the like.

A method of preparing the polyimide precursor composition, according to the present disclosure, may include the following steps: (a) preparing a first polyamic acid including a first block of a block copolymer by polymerizing biphenyl-tetracarboxylic dianhydride and para-phenylenediamine in an organic solvent; (b) preparing a second polyamic acid including the first and second blocks of the block copolymer by polymerizing biphenyl-tetracarboxylic dianhydride and m-tolidine in the first polyamic acid formed in step (a); and (c) preparing a third polyamic acid including the first, second, and third blocks of the block copolymer by polymerizing pyromellitic dianhydride and m-tolidine in the second polyamic acid formed in step (b).

In one embodiment, m-tolidine may have a content of 25 mol % or more and 40 mol % or less, and para-phenylenediamine may have a content of 60 mol % or more and 75 mol % or less, based on 100 mol % of the total content of the diamine component of the block copolymer. Additionally, biphenyl-tetracarboxylic dianhydride may have a content of 50 mol % or more and 65 mol % or less, and pyromellitic dianhydride may have a content of 35 mol % or more and 50 mol % or less, based on 100 mol % of the total content of the acid dianhydride component of the block copolymer.

In one embodiment, the biphenyl-tetracarboxylic dianhydride in the first block of the block copolymer may have a content of 40 mol % or more and 55 mol % or less based on 100 mol % of the total content of the acid dianhydride component of the block copolymer. Additionally, the biphenyl-tetracarboxylic dianhydride in the second block may have a content of 10 mol % or more based on 100 mol % of the total content of the acid dianhydride component in the polyimide film.

On the other hand, the biphenyl-tetracarboxylic dianhydride in the second block may have a content of 25 mol % or less based on 100 mol % of the total content of the acid dianhydride component in the polyimide film.

Additionally, the m-tolidine in the third block of the block copolymer may have a content of 10 mol % or more and 35 mol % or less based on 100 mol % of the total content of the diamine component in the polyimide film.

### MODE FOR INVENTION

Hereinafter, the action and effect of the present disclosure will be described in detail through specific examples of the present disclosure. However, such examples are provided only for illustrative purposes, and the scope of the present disclosure is not limited to the following examples.

### Preparation Example

NMP was introduced while injecting nitrogen into a 500 mL reactor equipped with a stirrer and nitrogen injection/discharge pipes, and the reactor temperature was set to 30° C. Next, para-phenylenediamine and m-tolidine as diamine components and biphenyl-tetracarboxylic dianhydride and pyromellitic dianhydride as acid dianhydride components were introduced in a predetermined order while being subjected to block copolymerization by raising the temperature to 40° C. under a nitrogen atmosphere to be heated with stirring for 120 minutes. As a result, a polyamic acid exhibiting a viscosity of 200,000 cP at 23° C. was prepared.

The prepared polyamic acid was rotated at a high speed of 1,500 rpm or more to remove gas bubbles. Then, a spin coater was used to coat a glass substrate with the resulting degassed polyimide precursor composition. Next, the resulting product was dried under a nitrogen atmosphere at a temperature of 120° C. for 30 minutes to form a gel film. The gel film was heated up to 450° C. at a rate of 2° C./min, subjected to heat treatment at 450° C. for 60 minutes, and then cooled down to 30° C. at a rate of 2° C./min to obtain a polyimide film.

Afterward, the polyimide film was dipped in distilled water and detached from the glass substrate. The polyimide film formed in such a manner had a thickness of 15 μm. The thickness of the polyimide film was measured using an electric film thickness tester purchased from Anritsu.

Hereinafter, the content of the diamine component in examples refers to the mol % of each diamine component based on 100 mol % of the total content of the diamine component in the polyimide film. Additionally, the content of the acid dianhydride component in examples refers to the mol % of each acid dianhydride component based on 100 mol % of the total content of the acid dianhydride component in the polyimide film.

### Example 1

A polyimide film was formed by introducing para-phenylenediamine (70 mol %), biphenyl-tetracarboxylic dianhydride (45 mol %), m-tolidine (15 mol %), biphenyl-tetracarboxylic dianhydride (15 mol %), m-tolidine (15 mol %), and pyromellitic dianhydride (40 mol %) in this order according to the preparation example described above as the diamine and acid dianhydride components and then copolymerizing the introduced components.

### Example 2

A polyimide film was formed by introducing para-phenylenediamine (70 mol %), biphenyl-tetracarboxylic dianhydride (50 mol %), m-tolidine (10 mol %), biphenyl-tetracarboxylic dianhydride (10 mol %), m-tolidine (20 mol %), and pyromellitic dianhydride (40 mol %) in this order according to the preparation example described above as the diamine and acid dianhydride components and then copolymerizing the introduced components.

### Example 3

A polyimide film was formed by introducing para-phenylenediamine (65 mol %), biphenyl-tetracarboxylic dianhydride (40 mol %), m-tolidine (10 mol %), biphenyl-tetracarboxylic dianhydride (10 mol %), m-tolidine (25 mol %), and pyromellitic dianhydride (50 mol %) in this order according to the preparation example described above as the diamine and acid dianhydride components and then copolymerizing the introduced components.

### Example 4

A polyimide film was formed by introducing para-phenylenediamine (60 mol %), biphenyl-tetracarboxylic dianhydride (40 mol %), m-tolidine (15 mol %), biphenyl-tetracarboxylic dianhydride (15 mol %), m-tolidine (25 mol %), and pyromellitic dianhydride (45 mol %) in this order according to the preparation example described above as the diamine and acid dianhydride components and then copolymerizing the introduced components.

### Example 5

A polyimide film was formed by introducing para-phenylenediamine (60 mol %), biphenyl-tetracarboxylic dianhydride (40 mol %), m-tolidine (10 mol %), biphenyl-tetracarboxylic dianhydride (10 mol %), m-tolidine (30 mol %), and pyromellitic dianhydride (50 mol %) in this order according to the preparation example described above as the diamine and acid dianhydride components and then copolymerizing the introduced components.

### Comparative Example 1

A polyimide film was formed by introducing para-phenylenediamine (55 mol %), biphenyl-tetracarboxylic dianhydride (50 mol %), m-tolidine (45 mol %), and pyromellitic dianhydride (50 mol %) in this order according to the preparation example described above as the diamine and acid dianhydride components and then copolymerizing the introduced components.

### Comparative Example 2

A polyimide film was formed by introducing m-tolidine (80 mol %), biphenyl-tetracarboxylic dianhydride (40 mol %), para-phenylenediamine (20 mol %), and pyromellitic dianhydride (60 mol %) in this order according to the preparation example described above as the diamine and acid dianhydride components and then copolymerizing the introduced components.

### Comparative Example 3

A polyimide film was formed by introducing m-tolidine (80 mol %), biphenyl-tetracarboxylic dianhydride (30 mol %), para-phenylenediamine (20 mol %), and pyromellitic dianhydride (70 mol %) in this order according to the preparation example described above as the diamine and acid dianhydride components and then copolymerizing the introduced components.

### Comparative Example 4

A polyimide film was formed by introducing m-tolidine (60 mol %), biphenyl-tetracarboxylic dianhydride (40 mol %), para-phenylenediamine (40 mol %), and pyromellitic dianhydride (60 mol %) in this order according to the preparation example described above as the diamine and acid dianhydride components and then copolymerizing the introduced components.

### Comparative Example 5

A polyimide film was formed by introducing para-phenylenediamine (80 mol %), biphenyl-tetracarboxylic dianhydride (70 mol %), m-tolidine (20 mol %), and pyromellitic dianhydride (30 mol %) in this order according to the preparation example described above as the diamine and acid dianhydride components and then copolymerizing the introduced components.

The components and contents thereof in the polyimide films formed according to Examples 1 to 5 and Comparative Examples 1 to 5 are shown in Table 1 below.

TABLE 1

| | | | Diamine component | | |
|---|---|---|---|---|---|
| | Acid dianhydride | | (mol %) | | |
| | component (mol %) | | m- | | Polyamic acid |
| | BPDA | PMDA | Tolidine | PPD | polymerization |
| | (mol %) | (mol %) | (mol %) | (mol %) | method |
| Example 1 | 60 | 40 | 30 | 70 | Block |
| | | | | | polymerization |
| Example 2 | 60 | 40 | 30 | 70 | Block |
| | | | | | polymerization |
| Example 3 | 50 | 50 | 35 | 65 | Block |
| | | | | | polymerization |
| Example 4 | 55 | 45 | 40 | 60 | Block |
| | | | | | polymerization |
| Example 5 | 50 | 50 | 40 | 60 | Block |
| | | | | | polymerization |
| Comparative | 50 | 50 | 45 | 55 | Block |
| Example 1 | | | | | polymerization |
| Comparative | 40 | 60 | 80 | 20 | Block |
| Example 2 | | | | | polymerization |
| Comparative | 30 | 70 | 80 | 20 | Block |
| Example 3 | | | | | polymerization |
| Comparative | 40 | 60 | 60 | 40 | Block |
| Example 4 | | | | | polymerization |
| Comparative | 70 | 30 | 20 | 80 | Block |
| Example 5 | | | | | polymerization |

### <Experimental Example> Evaluation of Dielectric Constant, Dielectric Dissipation Factor, Coefficient of Thermal Expansion, and Glass Transition Temperature

The dielectric constant, dielectric dissipation factor, coefficient of thermal expansion, and glass transition temperature were measured for each polyimide film formed in Examples 1 to 5 and Comparative Examples 1 to 5. The results thereof are shown in Table 2 below.

### (1) Measurement of Dielectric Constant (Dk)

For the dielectric constant (Dk), a sample was dried in an oven at 130° C. for 30 minutes and left for 24 hours in an environment where the relative humidity at 23° C. was 50%. Then, a network analyzer purchased from Keysight and an SPDR resonator purchased from QWED were used to measure a dielectric constant at 10 GHz.

### (2) Measurement of Dielectric Dissipation Factor (Df)

For the dielectric dissipation factor (Df), a sample was dried in an oven at 130° C. for 30 minutes and left for 24 hours in an environment where the relative humidity at 23° C. was 50%. Then, a network analyzer purchased from Keysight and an SPDR resonator purchased from QWED were used to measure a dielectric dissipation factor (Df) at 10 GHz.

### (3) Measurement of Coefficient of Thermal Expansion (CTE)

The coefficient of thermal expansion (CTE) was measured using a thermomechanical analyzer, Q400 model purchased from TA. Each polyimide film was cut into a size of a width of 4 mm and a length of 20 mm. While applying a tension of 0.05 N under a nitrogen atmosphere, the resulting film was heated from room temperature to 300° C. at a rate of 10° C./min and then cooled again at a rate of 10° C./min to measure the slope from 100° C. to 200° C.

### (4) Measurement of Glass Transition Temperature

For the glass transition temperature (Tg), the loss modulus and storage modulus of each film were calculated using DMA, and the inflection point in the tangent graph thereof was measured as the glass transition temperature.

TABLE 2

| | | | CTE | Tg |
|---|---|---|---|---|
| | Dk | Df | (ppm/° C.) | (° C.) |
| Example 1 | 3.6 | 0.0023 | 15 | 330 |
| Example 2 | 3.6 | 0.0024 | 17 | 322 |
| Example 3 | 3.6 | 0.0027 | 17 | 324 |
| Example 4 | 3.6 | 0.0025 | 20 | 324 |
| Example 5 | 3.6 | 0.0026 | 22 | 321 |
| Comparative Example 1 | 3.6 | 0.0035 | 24 | 310 |
| Comparative Example 2 | 3.4 | 0.0048 | 5 | 303 |
| Comparative Example 3 | 3.4 | 0.0053 | 1 | 311 |
| Comparative Example 4 | 3.6 | 0.0044 | 15 | 300 |
| Comparative Example 5 | 3.6 | 0.0060 | 7 | 295 |

As shown in Table 2 above, it is confirmed that the polyimide films, formed according to the examples of the present disclosure, not only exhibit a significantly low dielectric dissipation factor, which is 0.003 or less, but also show desired levels of coefficient of thermal expansion and glass transition temperature.

These results are achieved by the components and composition ratio specified herein, showing that the content of each component plays a decisive role.

On the other hand, due to one or more aspects of the dielectric dissipation factor, coefficient of thermal expansion, and glass transition temperature, the polyimide films of Comparative Examples 1 to 5, whose components differ from those in Examples 1 to 5, may have difficulties being used in electronic components where signal transmission occurs at high frequencies in gigahertz.

Although the present disclosure has been described above with reference to examples of the present disclosure, those skilled in the art will be able to make various applications and modifications based on the above contents within the scope of the present disclosure.

### INDUSTRIAL APPLICABILITY

As described above, the present disclosure provides a polyimide film having excellent highly heat-resistant properties, low-dielectric properties, and dimensional stability properties through a polyimide film composed of specific components in specific composition ratios and a polyamide precursor composition for preparing the same, which may thus be usefully applied to various fields in need of such properties, especially electronic components such as flexible metal-clad laminates.

1. A polyimide film comprising a block copolymer comprising:
a first block obtainable by imidizing a polyamic acid derived from a polymer of an acid dianhydride component comprising biphenyl-tetracarboxylic dianhydride (BPDA) and a diamine component comprising para-phenylenediamine (PPD);
a second block obtainable by imidizing a polyamic acid derived from a polymer of an acid dianhydride component comprising biphenyl-tetracarboxylic dianhydride and a diamine component comprising m-tolidine; and
a third block obtainable by imidizing a polyamic acid derived from a polymer of an acid dianhydride component comprising pyromellitic dianhydride (PMDA) and a diamine component comprising m-tolidine.

2. The polyimide film of claim 1, wherein polyimide film is obtainable by imidizing the polyamic acid derived from the polymer of the acid dianhydride component comprising biphenyl-tetracarboxylic dianhydride and pyromellitic dianhydride and the diamine component comprising para-phenylenediamine and m-tolidine.

3. The polyimide film of claim 1, wherein m-tolidine has a content of 25 mol % or more and 40 mol % or less, and para-phenylenediamine has a content of 60 mol % or more and 75 mol % or less, based on 100 mol % of the total content of the diamine component in the polyimide film.

4. The polyimide film of claim 1, wherein biphenyl-tetracarboxylic dianhydride has a content of 50 mol % or more and 65 mol % or less, and
pyromellitic dianhydride has a content of 35 mol % or more and 50 mol % or less, based on 100 mol % of the total content of the acid dianhydride component in the polyimide film.

5. The polyimide film of claim 1, wherein the biphenyl-tetracarboxylic dianhydride in the first block has a content of 40 mol % or more and 55 mol % or less based on 100 mol % of the total content of the acid dianhydride component in the polyimide film, and
the biphenyl-tetracarboxylic dianhydride in the second block has a content of 10 mol % or more based on 100 mol % of the total content of the acid dianhydride component in the polyimide film.

6. The polyimide film of claim 1, wherein the m-tolidine in the third block has a content of 10 mol % or more and 35 mol % or less based on 100 mol % of the total content of the diamine component in the polyimide film.

7. The polyimide film of claim 1, wherein a dielectric dissipation factor (Df) is 0.003 or less,
a coefficient of thermal expansion (CTE) is 13 ppm/° C. or higher and 23 ppm/° C. or lower, and
a glass transition temperature (Tg) is 320° C. or higher.

8. A multilayer film comprising:
the polyimide film of any one of claims 1 to 7; and
a thermoplastic resin layer.

9. A flexible metal-clad laminate comprising:
the polyimide film of any one of claims 1 to 7; and
an electrically conductive metal foil.

10. An electronic component comprising the flexible metal-clad laminate of claim 9.

11. A polyimide precursor composition comprising a block copolymer comprising:
a first block obtainable by reacting an acid dianhydride component comprising biphenyl-tetracarboxylic dianhydride (BPDA) and a diamine component comprising para-phenylenediamine (PPD);
a second block obtainable by reacting an acid dianhydride component comprising biphenyl-tetracarboxylic dianhydride and a diamine component comprising m-tolidine; and
a third block obtainable by reacting an acid dianhydride component comprising pyromellitic dianhydride (PMDA) and a diamine component comprising m-tolidine.
